(19) United States
(12) Patent Application Publication
(10) Pub. No.: US 2024/0159843 A1
(43) Pub. Date: May 16, 2024

(54) DEVICE AND METHOD FOR HEATING AND SIMULTANEOUSLY APPLYING A HIGH VOLTAGE TO AN ELECTRIC CABLE

(71) Applicant: NEXANS, Courbevoie (FR)

(72) Inventors: Patrick FORNAGE, Courbevoie (FR); Dimitri CHARRIER, MERCUER (FR); Raphaël GUFFOND, LYON (FR)

(21) Appl. No.: 18/384,941

(22) Filed: Oct. 30, 2023

(30) Foreign Application Priority Data
Nov. 2, 2022 (FR) 22 11409

(51) Int. Cl. G01R 31/59; G01R 31/12; G01R 31/14

(52) U.S. Cl. CPC G01R 31/59; G01R 31/1272; G01R 31/14

(57) ABSTRACT

A device (10) for heating and simultaneously applying a high voltage to an electric cable (12) includes the electric cable (12), an inductive transformer (14) connected to the electric cable (12), designed to heat the electric cable (12) to a first predetermined temperature, and a high-voltage transformer (16) connected between the electric cable (12) and ground, designed to apply a predetermined voltage of between 100 kV and 300 kV to the electric cable (12).

### RELATED APPLICATION

This application claims the benefit of priority from French Patent Application No. FR 22 11409, filed on Nov. 2, 2022, the entirety of which is incorporated by reference.

### FIELD OF THE INVENTION

The present invention relates to a device and to a method for heating and simultaneously applying a high voltage to an electric cable.

The invention belongs to the field of electric cables intended to transport energy and/or to transmit data. It is particularly applicable in the field of the development of high-voltage transmission cables.

### DESCRIPTION OF RELATED ART

During the development phase of a high-voltage transmission cable, in order to reproduce the operating conditions that the cable will encounter once it is in service, it is necessary to heat the cable when it is subjected to stress related to the application of a high AC or DC voltage.

Cable specimens under test are generally heated by immersing these specimens in a heated liquid, which may be water or a dielectric oil.

However, when a liquid medium is used to heat a cable, particularly in the case of an oil, it is not known how this liquid medium is likely to affect the mechanical and/or electrical properties of the cable. Furthermore, the heating source is located outside the cable, whereas, when the cable is actually in service, the heating generally stems from its main conductor, thereby constituting substantially different operating conditions.

### OBJECTS AND SUMMARY

The present invention aims to rectify the abovementioned drawbacks of the prior art.

To this end, the present invention proposes a device for heating and simultaneously applying a high voltage to an electric cable, the device being noteworthy in that it comprises:

the electric cable;
an inductive transformer connected to the electric cable, designed to heat the electric cable to a first predetermined temperature; and
a high-voltage transformer connected between the electric cable and ground, designed to apply a predetermined voltage of between 100 kV and 300 kV to the electric cable.

Thus, the superposition, on the cable, of the inductive transformer for heating the cable and of the high-voltage transformer for applying the stress related to the high voltage allows “dry” heating through the core of the cable, without the presence of oil, which could alter the mechanical and/or electrical properties of the materials forming the cable.

In one particular embodiment, the device furthermore comprises a tank containing water, in which the electric cable is at least partially immersed.

This makes it possible to ensure that the electric cable has a homogeneous temperature, without however using oil as liquid medium.

In one particular embodiment, this water is heated to a second predetermined temperature.

This makes it possible to improve the heating of the cable.

In one particular embodiment, the second predetermined temperature is equal to the first predetermined temperature.

In one particular embodiment, the first predetermined temperature is between 30° C. and 110° C.

For the same purpose as indicated above, the present invention also proposes a method for heating and simultaneously applying a high voltage to an electric cable by way of a device as briefly described above, which method is noteworthy in that it comprises the following steps:

heating the electric cable to said first predetermined temperature by way of the inductive transformer;
simultaneously applying said predetermined voltage of between 100 kV and 300 kV to the electric cable by way of the high-voltage transformer.

Since the particular features and the advantages of the method are similar to those of the device, they are not repeated here.

### BRIEF DESCRIPTION OF THE DRAWINGS

Other aspects and advantages of the invention will become apparent on reading the detailed description below of particular embodiments, which are given by way of entirely non-limiting examples, with reference to the appended drawings, in which:

FIG. 1 is a schematic depiction of a device according to the present invention, in one particular embodiment.

### DESCRIPTION OF EMBODIMENT(S)

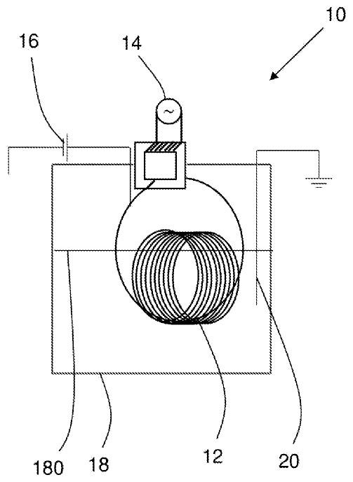

The circuit diagram of FIG. 1 shows, in one particular embodiment, a device 10 according to the present invention for heating and simultaneously applying a high voltage to an electric cable 12 in the development phase, as a test. The invention is applicable in particular, but not exclusively, to medium-voltage or high-voltage, AC or DC cables.

The device 10 comprises the electric cable 12, which is for example wound in a loop, the two ends of the loop being connected to one another.

The device 10 furthermore comprises an inductive transformer 14 connected to the electric cable 12. The inductive transformer 14 is flowed through by a current that creates a magnetic field that, through induction, creates a higher current in the electric cable 12. The inductive transformer 14 is thus able to heat the electric cable 12 to a first predetermined temperature.

By way of non-limiting example, the first predetermined temperature may be between 30° C. and 110° C.

The device 10 also comprises a high-voltage transformer 16 connected between the electric cable 12 and ground, designed to apply a predetermined voltage of between 100 kV and 300 kV to the electric cable 12. Indeed, the high-voltage transformer 16 converts a three-phase voltage of 440 V AC into a high voltage of 100 kV to 300 kV AC.

The high-voltage transformer 16 is connected to a conductor of the electric cable 12, for example by way of a terminal. The ends of the electric cable 12 are therefore stripped. For example, at the ends of the electric cable 12, the one or more semiconductor layers and the one or more electrically insulating layers of the electric cable are removed so as to expose the abovementioned conductor at the ends of the electric cable 12.

Optionally, as in the particular embodiment that is illustrated, the device 10 may furthermore comprise a tank 18 containing water, in which the electric cable 12 is at least partially immersed. In FIG. 1, the water level is designated by the reference 180. This water is possibly heated to a second predetermined temperature, for example equal to the first predetermined temperature.

Optionally, ground 20 is connected to the water in order to ground the water, such that the outer layer of the electric cable 12 in contact with the water is grounded, this outer layer being for example a semiconductor layer.

The method according to the present invention for heating and simultaneously applying a high voltage to the electric cable 12 by way of the device 10 thus comprises steps consisting in heating the electric cable 12 to the first predetermined temperature by way of the inductive transformer 14 and in simultaneously applying the predetermined voltage of between 100 kV and 300 kV to the electric cable 12 by way of the high-voltage transformer 16.

1. A device or heating and simultaneously applying a high voltage to an electric cable, said device comprising:
said electric cable;
an inductive transformer connected to said electric cable, designed to heat said electric cable to a first predetermined temperature; and
a high-voltage transformer connected between said electric cable and ground, designed to apply a predetermined voltage of between 100 kV and 300 kV to said electric cable.

2. The device according to claim 1, wherein said device further comprises a tank containing water, in which said electric cable is at least partially immersed.

3. The device according to claim 2, wherein the water is heated to a second predetermined temperature.

4. The device according to claim 3, wherein said second predetermined temperature is equal to said first predetermined temperature.

5. The device according to claim 1, wherein said first predetermined temperature is between 30° C. and 110° C.

6. A method for heating and simultaneously applying a high voltage to an electric cable by way of a device according to claim 1, wherein said method comprises the following steps:
heating said electric cable to said first predetermined temperature by way of said inductive transformer;
simultaneously applying said predetermined voltage of between 100 kV and 300 kV to said electric cable by way of said high-voltage transformer.
